(19) United States
(12) Patent Application Publication
(10) Pub. No.: US 2007/0063243 A1
(43) Pub. Date: Mar. 22, 2007

(54) Structure Of Embedded Capacitors And Fabrication Method Thereof

(76) Inventors: Wei-Chun Yang, Taipei City (TW); Chien-Wei Chang, Taoyuan Hsien (TW)

Correspondence Address: Lin & Associates Intellectual Property, Inc., Post Office Box 2339, Saratoga, CA, 95070-0339, US

(21) Appl. No.: 11/550,798

(22) Filed: Oct. 19, 2006

Related U.S. Application Data
(63) Continuation-in-part of application No. 10/998,076, filed on Nov. 26, 2004.

(51) Int. Cl. H01L 27/108; H01L 29/94; H01L 29/76; H01L 31/119

(52) U.S. Cl. 257/297; 257/301; 257/300

(57) ABSTRACT

A new structure is provided to replace the existing common planar capacitor structure used in printed circuit boards. The conventional common planar capacitor structure utilizes a single dielectric layer and embedded capacitors with different capacitances are achieved by adjusting the sizes of the embedded capacitors' conductive terminals. Since general applications usually require capacitors whose capacitance range covers several orders of magnitude, these embedded capacitors have significant differences in terms of their conductive terminals' sizes. This will make the manufacturing process more complicated and difficult. The new structure combines inorganic material having a specific dielectric constant and polymer having another specific dielectric constant into a singulated non-overlapping coplanar capacitor structure that is easy to manufacture and provides better precision.

This is a continuation-in-part of application Ser. No. 10/998,076, filed 2004 Nov. 26

### FIELD OF THE INVENTION

The present invention relates to the printed circuit board, and in particular to the structure and fabrication method of embedded capacitors in the printed circuit board.

### BACKGROUND OF THE INVENTION

The printed circuit board with embedded passive elements, due to its size reduction and better electrical characteristics, has become a mainstream technology for printed circuit boards.

Currently, as shown in FIG. 1, the embedded capacitors of a printed circuit board are usually formed using a common planar capacitor structure. With this structure, the embedded capacitors are made of a dielectric layer 13 having a specific dielectric constant on a substrate 10. On the bottom and top of the dielectric layer 13, the conductive terminals 11 and 12 of the embedded capacitors are formed by copper foils lamination against the dielectric layer 13 and then etching the copper foils through a lithography process. The common planar capacitor structure is named as such because the embedded capacitors of the printed circuit board share the same planar dielectric layer.

The common planar capacitor structure has a number of disadvantages. First, as shown in FIG. 1, conducting wires 14 usually pass through the dielectric layer 13. Due to the RC time delay effect, printed circuit boards using this structure are not suitable for high frequency or high speed applications. Moreover, severe electromagnetic interference is inevitable as there is no grounding or shielding effect at the non-capacitor areas of the structure.

Secondly, as the common planar capacitor structure utilizes a single dielectric layer, embedded capacitors having different capacitances are achieved by varying the sizes of the embedded capacitors' conductive terminals. However, general applications usually require capacitors whose capacitance range covers several orders of magnitude. These embedded capacitors therefore have significant differences in terms of their conductive terminals' sizes. This will make the manufacturing process more complicated and difficult.

In addition, the common planar capacitor structure requires coating capacitive paste to cover the full panel. The coating of the expensive capacitive paste at places where no capacitor is required is an unnecessary waste.

Also, the lamination process for copper foil terminals would cause a significant variance in the dielectric layer's thickness.

Several approaches have been proposed to improve the drawbacks of the conventional common planar capacitor structure. For example, U.S. Pat. No. 7,018,886 disclosed a method for forming shallow trenches having different trench fill materials, wherein a plurality of shallow trenches are filled with material with dielectric constants so that the subset of trenches filled with high dielectric constant can be used for coupling purposes and subset of trenches filled with low dielectric constant can be used as isolators. As the produced structure from the disclosed method includes a plurality of trenches etching into the substrate, the disclosed method is more complicated and potentially more expensive.

### SUMMARY OF THE INVENTION

To overcome the foregoing disadvantages of common planar capacitor structure, the present invention adopts inorganic material having a specific dielectric constant and a polymer having another specific dielectric constant, and combines them in a singulated coplanar capacitor structure.

In this new structure, the embedded capacitors are formed by coating directly over a substrate with a capacitive paste discretely or by laminating a dielectric sheet over the full panel and then etching the dielectric layer to form the capacitor pattern. The process can be repeated to coat a different dielectric sheet over the first pattern, including filling the area where the previous layer of dielectric is etched away. Therefore, the final structure of the embedded capacitors will include a plurality of coplanar dielectric patterns on top of the substrate. As these coplanar dielectric patterns are made of dielectric material with different dielectric constants, capacitors with a wide range of capacitance can co-exist on the same plane.

Traditional methods for forming the conductive terminals of the embedded capacitors such as the lamination of copper foils or using resin coated copper foils prepared in advance are not suitable for the new structure. The present invention therefore utilizes laser trimming or screen printing, along with various metallization processes, to form the upper conductive terminals of the embedded capacitors.

The present invention has the following advantages. First, the present invention has a better flexibility for routing and design than that of the common planar capacitor structure. The present invention also provides better signal integrity when used in high frequency and high speed electric circuits.

Secondly, as most embedded capacitors do not include reinforcement materials such as glass fibers and therefore there is a large variance in terms of the dielectric layer's thickness when fabricating RCC type of embedded capacitors using a lamination process, the present invention does not adopt the lamination process to avoid such variance.

Thirdly, as materials having different dielectric constants are used in the same layer of the new structure to achieve significantly different capacitances, the present invention requires less number of layers and thereby reduces manufacturing cost and increases the yield rate.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a sectional view of the common planar capacitor structure according to a prior art;

FIG. 2 shows a sectional view of the singulated coplanar capacitor structure according the present invention; and

FIGS. 3A-3E show the sectional views of the embodiment of FIG. 2 at different stages in the process of the present invention.

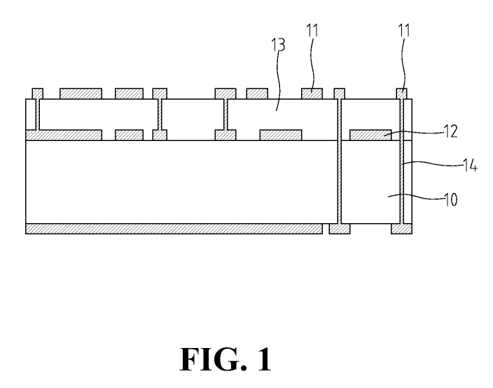

### DETAILED DESCRIPTION OF THE PREFERRED EMBODIMENTS

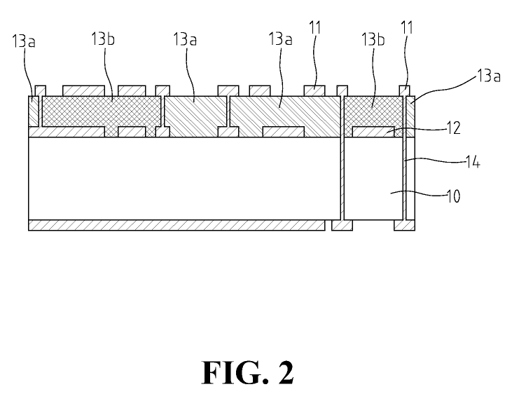

FIG. 2 is a sectional view of the singulated coplanar capacitor structure according the present invention. The structure of embedded capacitors in FIG. 2 includes a substrate 10, a plurality of bottom conductive terminals 12 formed on top of, a coplanar dielectric layer having at least two non-overlapping patterns of dielectric materials 13a, 13b, a plurality of top conductive terminals 11, and a plurality of conducting wires 14 for providing wiring connection.

The embedded capacitors are formed by the coplanar dielectric layer sandwiched between top conductive terminals 11 and bottom conductive terminals 12. The dielectric layer includes at least two non-overlapping patterns, with each pattern formed by a different dielectric material having a different dielectric constant. Each pattern of dielectric layer further includes a plurality of dielectric areas. The dielectric constant of the dielectric material, together with the size of the patterns and the size of the conductive terminals, determines the capacitance of the embedded capacitors. Therefore, the present structure allows the capacitances of the embedded capacitors to vary over a wide range by using different dielectric materials having different dielectric constants, while keeping the size of the capacitors within a certain range.

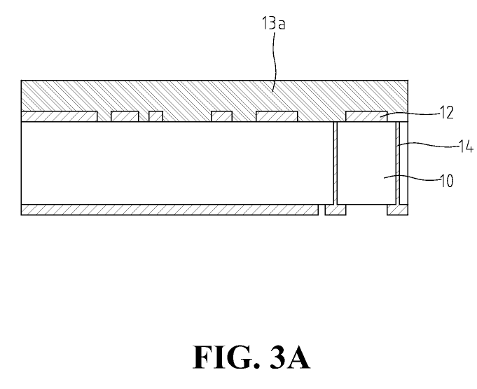

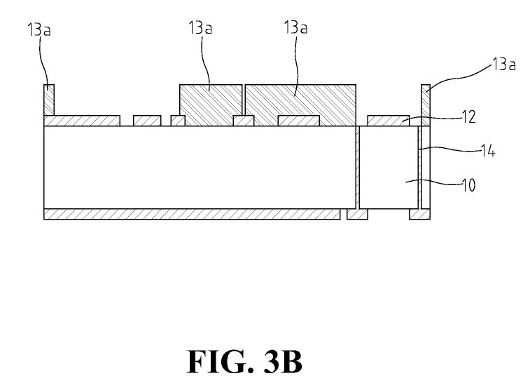

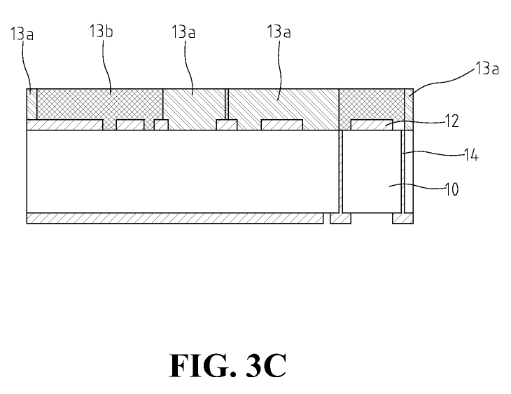

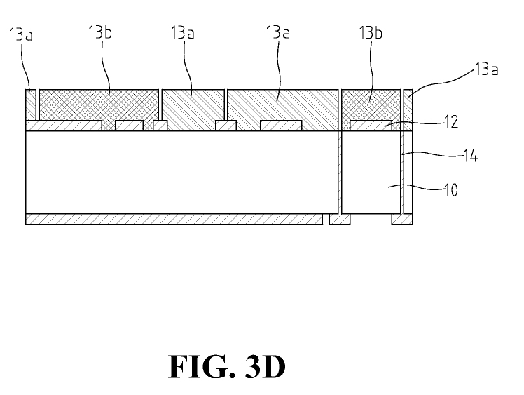

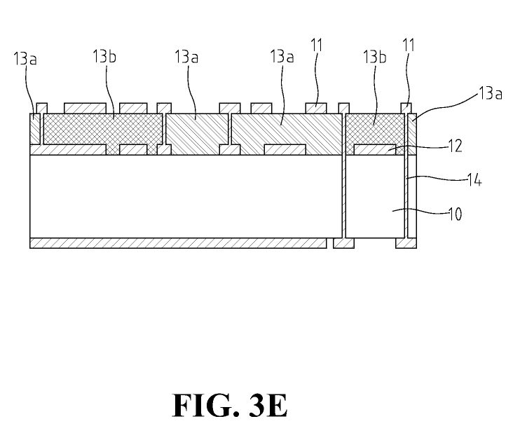

FIGS. 3A-3E show the sectional views of the embodiment of FIG. 2 at different stages in the process of the present invention. FIG. 3A shows the step of forming a first dielectric layer 13a on a substrate 10 having a plurality of conductive terminals 12 on top of substrate 10. Dielectric layer 13a is made of an inorganic material having a specific dielectric constant that is coated or laminated on the substrate 10. Then a subtractive method such as wet etching, laser trimming, or plasma etching is applied to the dielectric layer to etch away some part of dielectric layer 13a. The remaining dielectric layer 13a forms a pattern, as shown in FIG. 3B, where two areas of dielectric layer are shown. The pattern of dielectric layer 13a can also be formed directly on the substrate 10 using an additive method such as screen printing and thin film deposition. The inorganic material can be a polymer thick film material, a metallic oxide, or a ceramic capacitor material.

FIG. 3C shows a second dielectric layer 13b is formed at places where first dielectric layer 13a is etched away. Dielectric layer 13b is a polymer having a different dielectric constant coated on substrate 10. Then, a subtractive method such as wet etching, laser trimming, or plasma etching is applied to the dielectric layer to etch away some part of second dielectric layer 13b, as shown in FIG. 3D. The remaining second dielectric layer 13b forms a second pattern. Similarly, the second pattern of second dielectric layer 13b can also be formed directly on the substrate 10 using an additive method such as screen printing and thin film deposition. Second dielectric layer 13b is made of a polymer capacitive paste. The first and second patterns jointly form a singulated coplanar structure.

FIG. 3E shows that a plurality of upper conductive terminals 11 is formed on top of the two patterns. The top surfaces of the two patterns are first put through a roughening process. The roughening process can be performed using traditional dismear process, such as potassium permanganate solution or within a vacuum plasma environment. Then the roughened surfaces are metalized to form the upper conductive terminals 11. The metallization process can be chemical copper, copper plating, or vacuum sputtering.

Subsequently, the other layers of the printed circuit board can be developed with traditional procedures.

Compared with the common planar capacitor structure, the present invention has the following advantages.

The singulated structure of the present invention greatly increases the design flexibility of the printed circuit board. The signal integrity of the printed circuit board is also highly enhanced.

Embedded capacitors with a wide range of capacitances covering several orders of magnitude can be achieved all within a single layer of the printed circuit board. As no additional dielectric layer is required, the production cost is lower and the yield rate is better.

The metallization process adopted by the present invention has a better processing accuracy and selectiveness than those of subtractive methods using copper lamination and etching.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A structure of embedded capacitors, comprising:
a substrate;
a plurality of bottom conductive terminals located on top of said substrate;
a coplanar dielectric layer, located on top of said bottom conductive terminals and said substrate, said coplanar dielectric layer further comprising:
at least a first pattern made of a first dielectric material having a first dielectric constant; and
at least a second pattern made of a second dielectric material having a second dielectric;
where said first pattern and said second pattern being non-overlapping;
a plurality of top conductive terminals located on top of said coplanar dielectric layer; and
a plurality of conducting wires, for providing wiring connections.

2. The structure of embedded capacitors according to claim 1, wherein said embedded capacitors are formed by said coplanar dielectric layer sandwiched between said bottom conductive terminals and said top conductive terminals.

3. The structure of embedded capacitors according to claim 1, wherein said first pattern is made of a material selected from the group consisting of a polymer thick film material, a metallic oxide, or a ceramic capacitor material.

4. The structure of embedded capacitors according to claim 1, wherein said second pattern is made of a polymer capacitive paste.

5. The structure of embedded capacitors according to claim 2, wherein the capacitances of said embedded capacitors are determined by the sizes of said top and said bottom conductive terminals and said first and said second dielectric patterns, and said first and said second dielectric constants of said first and said second dielectric materials.
